(19) United States
(12) Patent Application Publication
(10) Pub. No.: US 2024/0405161 A1
(43) Pub. Date: Dec. 5, 2024

(54) LEDs AND METHODS OF MANUFACTURE

(71) Applicant: THE REGENTS OF THE UNIVERSITY OF MICHIGAN, Ann Arbor, MI (US)

(72) Inventors: Yakshita MALHOTRA, Ann Arbor, MI (US); Yifan SHEN, Ann Arbor, MI (US); Yuanpeng WU, Ann Arbor, MI (US); Yifu GUO, Ann Arbor, MI (US); Yixin XIAO, Ann Arbor, MI (US); Kai SUN, Ann Arbor, MI (US); Theodore NORRIS, Ann Arbor, MI (US); Zetian MI, Ann Arbor, MI (US); Ishtiaque NAVID, Ann Arbor, MI (US)

(21) Appl. No.: 18/648,202

(22) Filed: Apr. 26, 2024

Related U.S. Application Data
(60) Provisional application No. 63/528,041, filed on Jul. 20, 2023.
(60) Provisional application No. 63/462,031, filed on Apr. 26, 2023.

(51) Int. Cl. H01L 33/20; H01L 33/00; H01L 33/06; H01L 33/32

(52) U.S. Cl. CPC H01L 33/20; H01L 33/007; H01L 33/06; H01L 33/32

(57) ABSTRACT

In accordance with aspects of the present technology, a unique charge carrier transfer process from c-plane InGaN to semipolar-plane InGaN formed spontaneously in nanowire heterostructures can effectively reduce the instantaneous charge carrier density in the active region, thereby leading to significantly enhanced emission efficiency in the deep red wavelength. Furthermore, the total built-in electric field can be reduced to a few kV/cm by cancelling the piezoelectric polarization with spontaneous polarization in strain-relaxed high indium composition InGaN/GaN heterostructures. An ultra-stable red emission color can be achieved in InGaN over four orders of magnitude of excitation power range. Accordingly, aspects of the present technology advantageously provide a method for addressing some of the fundamental issues in light-emitting devices and advantageously enables the design of high efficiency and high stability optoelectronic devices.

### CROSS-REFERENCE TO RELATED APPLICATIONS

This application claims the benefit of U.S. Provisional Patent Application No. 63/528,041 filed Jul. 20, 2023, and U.S. Provisional Patent Application No. 63/462,031 filed Apr. 26, 2023, both of which are incorporated herein in their entirety.

### BACKGROUND

High efficiency light emitting devices (LEDs) with characteristic length scales on the order of microns or less, also known as μLEDs, have been under intense investigations for their immense promise in various display and communications scenarios. Among the many material systems investigated for μLEDs, the III-nitride family possesses many desirable material properties such as comparatively low surface recombination velocities and excellent wavelength tunability. To date, however, it has remained a challenge to achieve efficient green and red emitting μLEDs, largely due to the presence of extensive defects and dislocations, the strain-induced quantum-confined Stark effect, the enhanced surface recombination and poor p-type doping related to the top-down etching. Moreover, it has remained difficult to achieve the high levels of indium incorporation required for a red emitting indium gallium nitride (InGaN) active region. The incorporation of high indium composition causes alloy substitutional disorder in the active region and reduces the exciton binding energy, which enhances the Auger recombination coefficient. Polar nitrides also suffer from quantum confined stark effect (QCSE) due to spontaneous and piezoelectric polarizations, which reduces the overlap of electron-hole wavefunctions and causes color instability. InGaN based visible light μLEDs with efficient and stable emission over a wide luminosity range are desired for next generation displays, communications and other technologies.

### SUMMARY

The present technology may best be understood by referring to the following description and accompanying drawings that are used to illustrate embodiments of the present technology directed toward light emitting devices.

In one embodiment, a light emitting device can include a photonic crystal component and a N-polar nanowire component. The N-polar nanowire component can comprise a plurality of c-plane N-polar quantum confined nanostructures. The c-plane N-polar quantum confined nanostructures can further include a semipolar transition between the c-plane nanostructure face and nanostructure walls. The photonic crystal component can comprise a cross-sectional nanostructure width and a sub-micrometer nanostructure lattice constant length configured for green or red light emission by the light emitting device.

In another embodiment, a method of manufacturing a light emitting device can comprise bottom-up fabricating a plurality of type III-V semiconductor nanostructures in a photonic crystal. The bottom-up fabrication can comprise selective area epitaxy depositing N-polar quantum-confined nanostructures having sub-micrometer cross-sectional nanostructure width and sub-micrometer nanostructure lattice constant length. The selective area epitaxy depositing N-polar quantum-confined nanostructures can include a semipolar transition between a c-plane nanostructure face of the nanostructure sidewalls.

In yet another embodiment, a light emitting device comprising a plurality of nanostructures including N-polar quantum-confined active regions have both c-plane and semipolar plane lattice, wherein the plurality of nanostructures have a sub-micrometer cross-sectional width and sub-micrometer separation between the plurality of nanostructures. The N-polar quantum-confined active regions can comprise N-polar indium gallium nitride (InGaN) and gallium nitride (GaN) multiple quantum dot (MQD) nanostructures having a semipolar transition between a c-plane face and walls of the plurality of nanostructures. The N-polar quantum-confined active regions can comprise N-polar nanostructures including an indium gallium nitride (GaN) single segment (SS) active region disposed on indium gallium nitride (InGaN) and gallium nitride (GaN) short-period superlattice (SPS) having a semipolar transition between a c-plane face and walls of the plurality of nanostructures.

In yet another embodiment, method of manufacturing a light emitting device comprising bottom-up fabricating a plurality of nanostructures including N-polar quantum-confined active regions having a semipolar plane lattice transition between a c-plane lattice face and sidewalls of the quantum-confined active regions. The bottom-up fabricating of the plurality of nano-structures can comprise selective area epitaxy depositing gallium nitride (GaN) short-period superlattice (SPS) regions, wherein epitaxy deposition parameters are configured to deposit the gallium nitride (GaN) with a nitride termination. The bottom-up fabricating can further comprise selective area epitaxy depositing indium gallium nitride (InGaN) and gallium nitride (GaN) single segment (SS) active regions on the gallium nitride (GaN) short-period superlattice (SPS) regions, wherein the epitaxy deposition parameters are configured to deposit the indium gallium nitride (InGaN) and gallium nitride (GaN) single segment (SS) with the nitride-termination, a c-plane lattice on a face of the indium gallium nitride (InGaN) and gallium nitride (GaN), and a spontaneously formed semipolar transition between the c-plane lattice of the face and sidewalls of the indium gallium nitride (InGaN) and gallium nitride (GaN).

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter.

### BRIEF DESCRIPTION OF THE DRAWINGS

Embodiments of the present technology are illustrated by way of example and not by way of limitation, in the figures of the accompanying drawings and in which like reference numerals refer to similar elements and in which:

FIGS. 1A-1C illustrate ultrahigh efficiency green emitting μLED effects, in accordance with aspects of the present technology.

FIGS. 2A-2D illustrate high efficiency red emitting LED effects, in accordance with aspects of the present technology.

FIG. 3 shows an exemplary nanowire, in accordance with aspects of the present technology.

FIGS. 4A and 4B show exemplary semiconductor crystalline structures, in accordance with aspects of the present technology.

FIG. 5 shows a method of manufacturing the nanowire, in accordance with aspects of the present technology.

FIG. 6 shows a selective area epitaxy fabrication method, in accordance with aspects of the present technology.

FIGS. 7A-7C show schematics and structural characterization of a nanowire array, in accordance with aspects of the present technology.

FIGS. 8A-8C show variations in photoluminescence peak wavelength due to varying nanowire diameter, in accordance with aspects of the present technology.

FIG. 9 shows aspects of a μLED device including an N-polar quantum-confined active region having both c-plane and semipolar plane lattice, along with comparison to other conventional μLEDs,

FIG. 10 shows photoluminescence spectra and energy transfer mechanisms, in accordance with aspects of the present technology.

FIG. 11 shows photoluminescence, radiative lifetime emission, relative quantum efficiency and peak wavelength, in accordance with aspects of the present technology.

FIG. 12 shows net-induced fields due to spontaneous polarization and piezoelectric polarization, in accordance with aspects of the present technology.

### DETAILED DESCRIPTION

Reference will now be made in detail to the embodiments of the present technology, examples of which are illustrated in the accompanying drawings. While the present technology will be described in conjunction with these embodiments, it will be understood that they are not intended to limit the invention to these embodiments. On the contrary, the invention is intended to cover alternatives, modifications and equivalents. Furthermore, in the following detailed description of the present technology, numerous specific details are set forth in order to provide a thorough understanding of the present technology. However, it is understood that the present technology may be practiced without these specific details. In other instances, well-known methods, procedures, components, and circuits have not been described in detail as not to unnecessarily obscure aspects of the present technology.

Optoelectronic devices, in accordance with aspects of the present technology, can include one or more nanowires having a superlattice structure underlaying an active region. Each nanowire can have a micrometer or sub-micrometer dimension. Embodiments of the present technology can include high efficiency micrometer and sub micrometer (e.g., nanometer) scale green and red light emitting devices, herein after referred to as μLEDs. The efficiency bottleneck of μLEDs can be fundamentally addressed by the novel presented systems and methods of the present technology utilizing bottom-up III-nitride nanostructures.

In one exemplary implementation, green and red light emitting μLEDs with an external quantum efficiency of 25% and 8% are demonstrated, respectively. These are usually considered high values compared to traditional approaches. In one embodiment, selective area epitaxy is employed as the material synthesis platform. Due to efficient strain relaxation, such bottom-up nanostructures are largely free of dislocations. In one embodiment, by exploiting the large exciton binding energy and oscillator strength of quantum-confined InGaN nanostructures, the external quantum efficiency of a green emitting μLED can be dramatically improved from ˜4% to >25%. In one exemplary implementation, the dramatically improved efficiency is attributed to the utilization of semipolar planes in strain-relaxed nanostructures to minimize polarization and quantum-confined Stark effect and the formation of nanoscale quantum-confinement to enhance electron-hole wavefunction overlap. In one embodiment, a novel approach includes an InGaN/GaN short period superlattice together with an InGaN quantum dot active region to achieve high efficiency red emission. In one exemplary implementation, a maximum quantum efficiency of >7% can be achieved. The presented novel systems and methods offer a viable path to achieve high efficiency micrometer and sub-micrometer scale LEDs for a broad range of applications including mobile displays, virtual/augmented reality, biomedical sensing, and high-speed optical interconnects, that were difficult for conventional quantum well based LEDs.

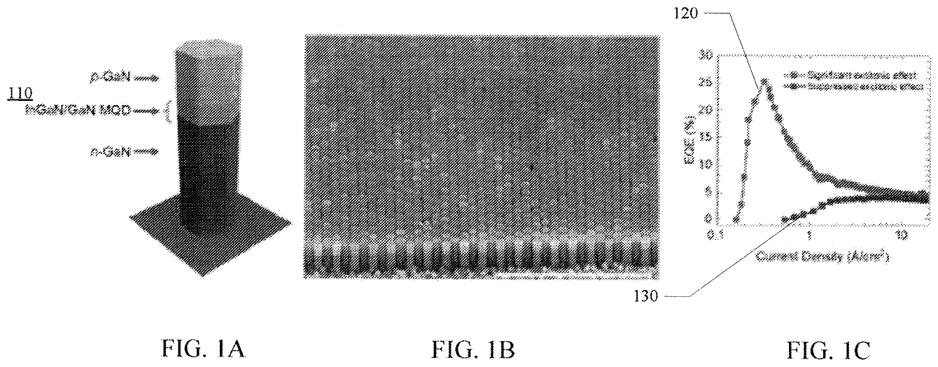

FIGS. 1A-1C illustrate ultrahigh efficiency green emitting μLED effects. FIG. 1A is a diagram of an exemplary μLED design, with a green nGaN/GaN multiple-quantum-dot (MQD) structure 110 serving as the active region in accordance with one embodiment. FIG. 1B is a block diagram of scanning electron microscope results of such a nanowire array in accordance with one embodiment. FIG. 1C is a graphical representation of exemplary variation in external quantum efficiency due to differences in nanowire diameters, with the first curve 120 coming from a thin nanowire diameter array and the second curve 130 coming from a larger diameter array is accordance with one embodiment. The thinner diameter array allows for more active region formation on the semi-polar plane rather than the polar c-plane, thus allowing for radiative excitonic recombination channels that are more efficient than traditional free carrier radiative recombination for InGaN.

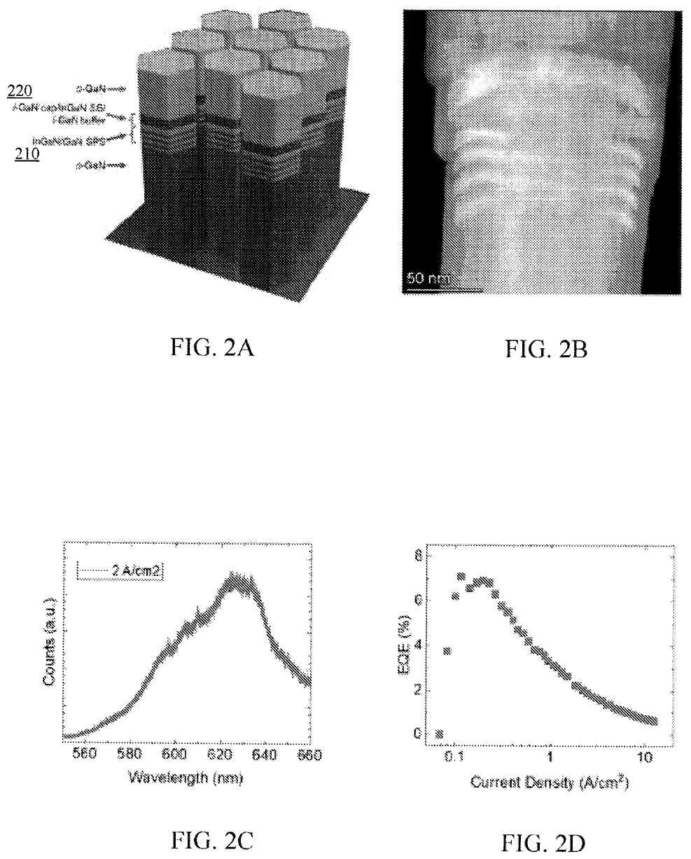

FIGS. 2A-2D illustrate high efficiency red emitting LED effects. FIG. 2A is a diagram of an exemplary nanowire design in accordance with one embodiment, which employs a short-period superlattice (SPS) 210 that allows for high levels of indium (In) incorporation in the single segment (SS) active region 220. FIG. 2B is an exemplary high angle annular dark field scanning transmission electron micrograph of one such nanowire in accordance with on embodiment, where the four layers of SPS indium gallium nitride (InGaN) and the single segment active region InGaN are visible at a higher contrast, as InGaN has a higher atomic number than gallium nitride (GaN). FIG. 2C is a graph of exemplary electroluminescence of a red emitting LED at 2 A/cm2 in accordance with one embodiment. FIG. 2D is a graph of an exemplary external quantum efficiency (EQE) of such red emitting LED devices that can reach >7% in accordance with one embodiment.

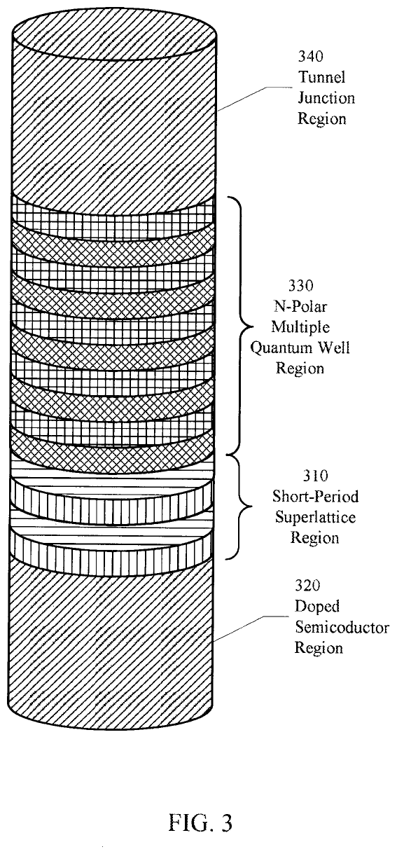

Referring to FIG. 3, an exemplary nanowire, in accordance with aspects of the present technology, is shown. The nanowire 300 can include a short period superlattice (SPSL) region 310 disposed on a doped semiconductor region 320. The nanowire 300 further includes an N-polar multiple quantum dot (MQD) region 330, in one implementation, disposed on the short period superlattice (SPSL) region 310. In other implementations, a N-polar single segment quantum dot region can be disposed on the short period superlattice (SPSL) region 310. The nanowire 300 can further include a tunnel junction region 340 disposed on the N-polar multiple quantum well (MQW) region 330 or N-polar single segment quantum dot region.

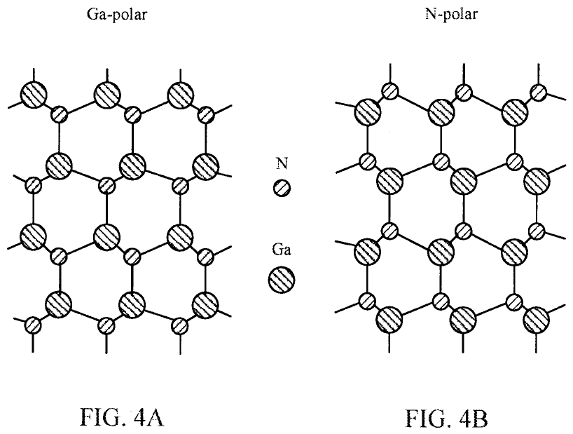

Referring now to FIGS. 4A and 4B, exemplary semiconductor crystalline structures are shown. FIG. 4A, illustrates a Ga-polar atomic structure. In the Ga-polar atomic structure, gallium (Ga) atoms terminate the gallium nitride (GaN) semiconductor crystalline structure along the surface. Conventional metal-organic chemical vapor deposition (MOCVD) utilized to fabricate gallium nitride (GaN) based semiconductor nanowires often result is Ga-polar atomic structures. FIG. 4B illustrates a N-polar atomic structure. In the N-polar atomic structures, nitrogen (N) atoms terminate the gallium nitride (GaN), aluminum nitride (AlN), indium nitride (IN), indium gallium nitride (InGaN), aluminum gallium nitride (AlGaN) or the like semiconductor crystalline structure along the surface. To achieve N-polar atomic structures a number of factors impact the formation of the N-polar crystalline structure. Among them are: (1) the choice of the substrate and its surface condition, (2) initial nitridation of the substrate to form a N-rich surface, (3) the use of a suitable nucleation (or buffer) layer, (4) avoidance of inversion domain detects at initial stages of growth, and (5) maintenance of the N-polar growth orientation as the layer is deposited to its desired thickness.

Referring again to FIG. 3, the doped semiconductor region 320 can comprise a group III-V compound semiconductor with a first type of doping and a N-polar lattice geometry (e.g., nitride terminated lattice geometry). In one implementation, the doped semiconductor region 320 can be a silicon (Si) doped (e.g., n-doped) gallium-nitride (GaN) region. In one embodiment, the short period superlattice (SPSL) region can be a short period (e.g., few atomic layers) structure of group III-V compound semiconductor atomic monolayers. In one implementation, the short period superlattice (SPSL) region can include m layers of indium gallium nitride (InGaN) and n layers gallium nitride (GaN) arranged in a short period of 3-7 interleaved layers. In one embodiment, the N-polar multiple quantum dot (MQD) region 330 can be a group III-V compound semiconductor of alternating quantum dots (QD) and quantum barriers (WB). In one implementation, the N-polar multiple quantum dot (MQD) region 330 can be a plurality of alternating indium gallium nitride (InGaN) quantum dots (QD) and gallium nitride (GaN) quantum barriers (QB). The N-polar doped semiconductor region 320 and/or the N-polar short-periods superlattice region 310 can be a N-polar template for the N-polar multiple quantum dot (MQD) region 310. In one embodiment, the tunnel junction region 340 can comprise a group III-V compound semiconductor with a second type of doping. In one implementation, the tunnel junction region 340 can be a magnesium (Mg) doped (e.g., p-doped) gallium-nitride (GaN) region. The nanowire 300 can have a substantially hexagonal, square, rectangular, rhombic, polygonal, circular or elliptical cross-sectional shape.

In one implementation, the short period superlattice (SPSL) region 310 relaxes/reduces strain. The short period superlattice (SPSL) region 310 can also facilitate incorporation of more quantum configurations (e.g., quantum wells, quantum lines, quantum dots, nanoclusters, etc.). In one implementation, short period superlattice (SPSL) region 310 is configured to incorporate more indium (In) within the InGaN N-polar multiple quantum well (MQW) region 330. The short period superlattice (SPSL) region 310 can also help facilitate reduction of extensive defects and dislocations (e.g., for indium-rich InGaN quantum wells, etc.), strain induced quantum-confined Stark effect, and etch-induced surface damage during the fabrication of quantum well μLEDs.

In one embodiment, the m layers of the short period superlattice (SPSL) can have a high elastic constant and the n layer can have a low elastic constant (or vise versa, etc.). In one embodiment, the short period superlattice (SPSL) region can include a lower dimensional structure (e.g., an array of quantum dots, quantum wires, etc.). In one embodiment, the materials of the short period superlattice (SPSL) region can have different band gaps. In one exemplary implementation, the materials may be divided by the element groups IV, III-V and II-VI. In one embodiment, at least two of the plurality of the quantum dot (QD) regions within the N-polar quantum well (QW) regions are not uniform. In one embodiment, N-polar quantum dot (MQD) region is considered an intermediate region between a p-type region and a n-type region (e.g., a P-I-N configuration, etc.).

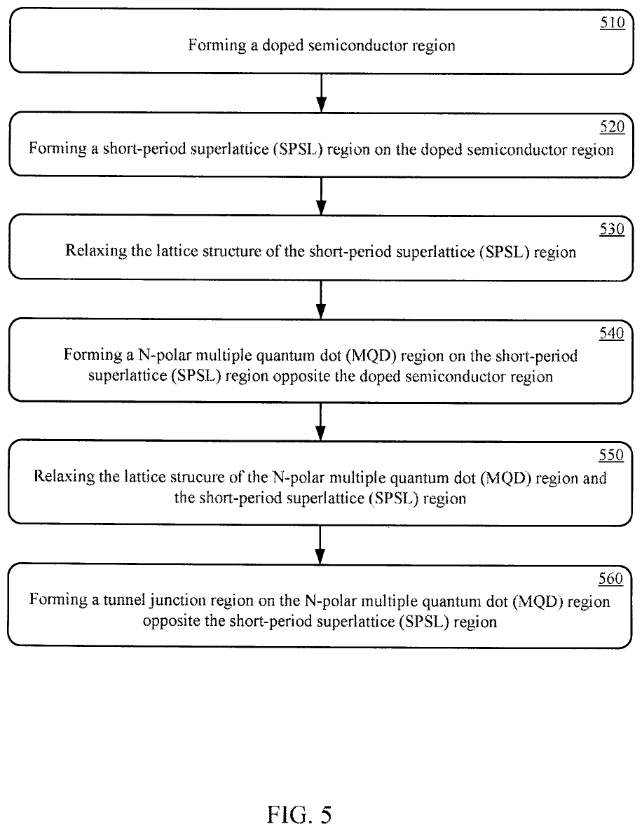

Referring now to FIG. 5, a method of manufacturing the nanowire, in accordance with aspects of the present technology, is shown. The method of manufacture can utilize a bottom-up fabrication process to fabricate micrometer or sub-micrometer nanowire structures. The method can include forming a first doped semiconductor region, at 510. The semiconductor region can be doped with a first type of dopant. In one implementation, selective area epitaxy can be used to grow an approximately 500 nm thick group III-V semiconductor compound having a first dopant type, such as silicone (Si) doped gallium nitride (GaN). In one implementation, plasma-assisted molecular beam epitaxy (PA-MBE) can be utilized to form the doped semiconductor region. The plasma-assisted molecular beam epitaxy (PA-MBE) parameters can be configured to produce a doped semiconductor region with a submicron lateral width. The plasma-assisted molecular beam epitaxy (PA-MBE) parameters can also be configured to produce a doped semiconductor region with a N-polar crystalline lattice structure.

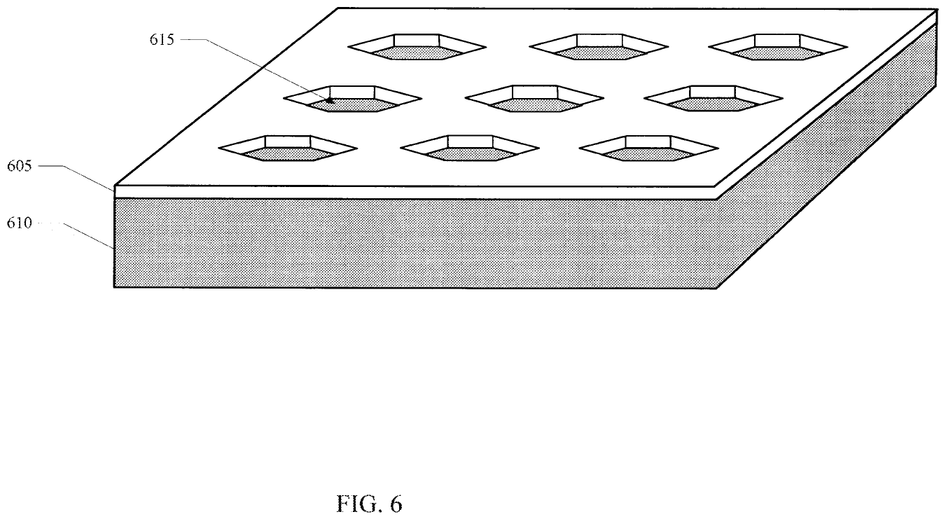

Referring now to FIG. 6, a selective area epitaxy fabrication method is illustrated. Selective area epitaxy can begin with forming patterned mask 605 on a prepared substrate 610. The patterned mask 605 can include an array of openings 615. The openings 615 can have a predetermined cross-sectional width (a) (also referred to as lateral size), and separation (b) (also referred to as lattice constant). Under select conditions, type III-V semiconductor device layers, of for silicone (Si) doped gallium nitride (GaN), will grow on the exposed substrate, but not on the mask, hence the selectivity of the epitaxy process. In one implementation, the cross-sectional width (a) can be the same for each opening, the separation (b) can also be the same. In other implementations, the cross-section width and or separation can vary in one or more patterns. For example, a first cluster of openings for implementing cluster of red light emitting nanowires (e.g., red pixel) can have a first cross-sectional width and a first separation, while a cluster of green light emitting nanowires (e.g. green pixel) can have a second cross-section width and second separation.

Referring again to FIG. 5, the short period superlattice (SPSL) region can be formed on the doped semiconductor region, at 520. In one implementation, plasma-assisted molecular beam epitaxy (PA-MBE) can be used to grow a plurality of periods of atomic monolayers, such as a Si-doped indium gallium nitride (InGaN) layers and gallium nitride (GaN) layers. In one implementation, plasma-assisted molecular beam epitaxy (PA-MBE) parameters can be configured to produce a short period superlattice (SPSL) region with a N-polar crystalline lattice structure. The plasma-assisted molecular beam epitaxy (PA-MBE) parameters can also be configured to produce a short period superlattice (SPSL) region, on the doped semiconductor region, with a submicron lateral width substantially the same as the doped semiconductor region. At 530, the lattice structure of the short period superlattice (SPSL) region can be relaxed. In one implementation, an in situ anneal can be performed after forming the short period superlattice (SPSL) region to reduce the density of defects.

At 540, a N-polar multiple quantum dot (MQD) region can be formed on the short period superlattice (SPSL) region opposite the doped semiconductor region. In one implementation, the plasma-assisted molecular beam epitaxy (PA-MBE) can be used to grow a plurality of periods of quantum dots (QD) and quantum barriers (QB). In one implementation, plasma-assisted molecular beam epitaxy (PA-MBE) parameters can be configured to produce the multiple quantum dot (MQD) region with the N-polar crystalline lattice structure. The short period superlattice (SPSL) region and or the doped semiconductor region can act as a template for the N-polar crystalline lattice structure deposited multiple quantum dot (MQD) region. For example, short period superlattice (SPSL) region and the doped semiconductor region can be deposited with N-polar lattice that is a template for forming an N-polar multiple quantum dot (MQD) region. The plasma-assisted molecular beam epitaxy (PA-MBE) parameters can also be configured to produce a multiple quantum dot (MQD) region, on the short period superlattice (SPSL) region, with a submicron lateral width substantially the same as the short period superlattice (SPSL) region and the doped semiconductor region. At 550, the lattice structure of the N-polar multiple quantum dot (MQD) region can be relaxed. In one implementation, an in situ anneal can be performed after forming N-polar multiple quantum dot (MQD) region to reduce the density of defects.

At 560, the tunnel junction region can be formed on the N-polar multiple quantum well (MQW) region opposite the short period superlattice (SPSL) region. The tunnel junction region can be a semiconductor doped with a second type of dopant. In one implementation, plasma-assisted molecular beam epitaxy (PA-MBE) can be used to grow an approximately 260 nm group III-V compound semiconductor having a first dopant type, such a magnesium (Mg) doped (p-type) GaN layer. In one implementation, plasma-assisted molecular beam epitaxy (PA-MBE) parameters can be configured to produce the tunnel junction region with the N-polar crystalline lattice structure. The plasma-assisted molecular beam epitaxy (PA-MBE) parameters can also be configured to produce a tunnel junction region, on the multiple quantum dot (MQD) region, with a submicron lateral width substantially the same as the multiple quantum dot (MQD) region, the short period superlattice (SPSL) region and the doped semiconductor region. The method of manufacturing the nanowire can further include a number of other fabrication processes not necessary for an understanding of aspects of the present technology, and therefore are not described herein.

Embodiments of the present technology can include multicolor micrometer scale light emitting devices monolithically grown on the same chip. Micro LEDs have emerged as a strong contender for next generation display devices due to their high efficiency, fast response, high brightness, and extended lifetime. For practical applications, it is highly desired that full color LEDs can be monolithically integrated on the same chip, which, however, has remained extremely challenging to achieve via the conventional quantum well based approach. In one embodiment, N-polar indium gallium nitride (InGaN) based μLEDs that are synthesized via selective area plasma assisted molecular beam epitaxy, have achieved record levels of efficiency at the micrometer and sub-micrometer device scale, with 25% external quantum efficiency (EQE) for green emission and 8% EQE for red. In one exemplary implementation, such advances are enabled by selective area plasma assisted molecular beam epitaxy, in which, unlike thin film epitaxial growths, local kinetics can be controlled by substrate mask patterning. In one embodiment, the selective area openings on the substrate mask enable the formation of a photonic crystal. In one embodiment, the effect of pattern opening diameters on the InGaN photoluminescence (PL) wavelength are demonstrated. In one embodiment, for a multiple-quantum-disk structure designed for green emission, given a certain photonic crystal lattice constant, the PL peak wavelength can vary over nearly 100 nm as the opening diameter varies over 60 nm, thereby enabling the achievement of multi-color emission for LED structures grown on a single chip in a single epitaxial step. More importantly, in one exemplary implementation strong coherent emission over a wide wavelength range for such nanowire photonic crystal LED structures is demonstrated. Their emission wavelengths can be precisely controlled and tuned by varying the design and processing parameters. Such nanowire photonic crystal devices not only enable a wide range of wavelength tuning but also lead to high efficiency and highly directional emission which is desired for future near-eye display applications. By further optimizing the design and epitaxial process, the realization of full-color emission for such unique N-polar III-nitride photonic nanostructures can be realized. In one embodiment, high efficiency micrometer scale green and red LEDs that can exhibit strong coherent emission is achieved.

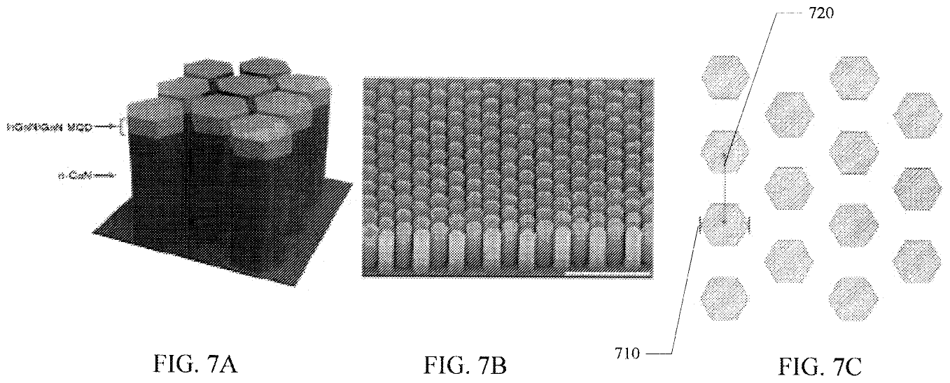

Embodiments of the present technology can also include combinations. FIG. 7A-7C are related to schematics and structural characterization of a nanowire array. FIG. 7A is an exemplary schematic of the nanowire array with a green InGaN/GaN multiple-quantum-dot (MQD) design for the active region. FIG. 7B is an exemplary sample scanning electron microscopy of such a nanowire array in accordance with one embodiment. The scale bar (in white) is 1 micron. FIG. 7C is an exemplary layout of a two-dimensional honeycomb shaped photonic crystal in accordance with one embodiment, which is parametrized by nanowire cross-sectional width (a) and separation (b) (lattice constant length). The two vertical lines 710 indicate the nanowire cross-sectional width (a), and the vertical double-headed arrow 720 indicates the separation (lattice constant length) in the sample crystal design.

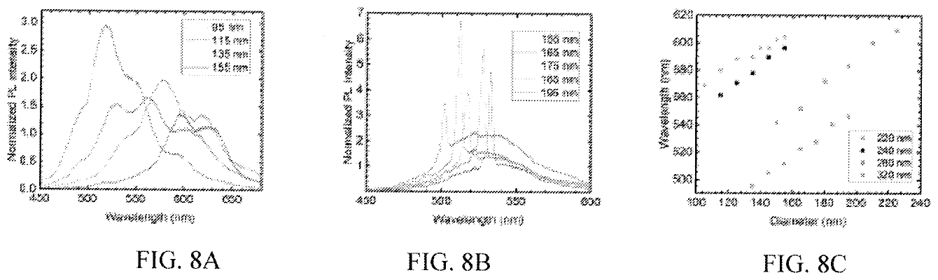

FIG. 8A-8C are related to variations in photoluminescence peak wavelength due to varying nanowire diameter. FIG. 8A is a graph of exemplary photoluminescence spectra for nanowire arrays with a classic multiple-quantum-disk design but different nanowire diameters in accordance with one embodiment. In one embodiment, the lattice constant is 240 nm for the curves. FIG. 8B is a graph of exemplary peak wavelength of photonic crystal mode emissions that can be modulated with the nanowire diameter as well, in accordance with one embodiment. In one embodiment, the lattice constant is 280 nm for the curves. FIG. 8C is an exemplary scatterplot showing the effect of peak wavelength modulation persists for different lattice constants in accordance with one embodiment.

In one embodiment, presented systems and methods can enable photonic crystal photoluminescent spectrum (e.g., similar to FIG. 8B, etc.). In one exemplary implementation the photonic crystal mode emission is out of what are N polar selective area growth nanowires. In one embodiment, the wavelength is extremely predictable (e.g., nice straight linear dependency (diagonal lines) based on the lattice constants and diameter similar to FIG. 8C. etc).

In one embodiment, a light emitting device includes photonic crystal μLEDs. In one exemplary implementation, changes in diameters and periods can produced different wavelengths. In one embodiment, a light emitting device includes N-polar μLEDs. In one embodiment, a light emitting device includes a combination of an N-polar μLED with a photonic crystal μLED. In one embodiment, the light emitting device includes a partial or half μLED (e.g., without contacts for biasing, etc.). In one embodiment, a light emitting device includes tunability of photonic crystal μLED. In one embodiment, a light emitting device includes a photonic crystal effect with an N-polar nanowire. In one exemplary implementation, performance of a light emitting device including a photonic crystal effect with an N-polar nanowire is similar to the performance of novel μLEDs described herein. It is appreciated that photoluminescence, electroluminescence, and combinations of both can be measured. In one embodiment, photoluminescence is being measured and not electroluminescence, and so on.

In one embodiment, the top of a N polar nanowire structure is flat (e.g., top 110, 210 and 310 in FIGS. 1A, 2A, 3A respectively, etc.) and wavelengths can be controlled by varying the N polar nanowire structure configuration (e.g., diameter, spacing, shape, etc.). In one exemplary implementation, a light emitting device include a N polar nanowire structure and wavelength tunability with diameter variation. In one exemplary implementation, a light emitting device include a N polar nanowire structure and wavelength tunability with diameter variation.

In one embodiment, the active region of the nanowire can comprise a group III-nitride quantum well or multi-quantum well active region. The superlattice structure can comprise a strain relaxed short period superlattice (SPSL) region. In one implementation, the quantum well active region can comprise one or more indium gallium nitride (InGaN) quantum well layers disposed between gallium nitride (GaN) barrier layers. The strain relaxed short period superlattice (SPSL) region can comprise a plurality of strain relaxed pairs of indium gallium nitride (InGaN) and gallium nitride (GaN) layers.

Strain relaxation can be achieved by adopting an InGaN/GaN superlattice structure preceding the multiple quantum well (MQW) active region. Meanwhile, nanowire structures offer additional strain relaxation due to a high surface to volume ratio. Moreover, a core-shell structure can be formed in nanowire InGaN/GaN heterostructure due to a unique migration assisted growth mechanism, which suppresses non-radiative surface recombination.

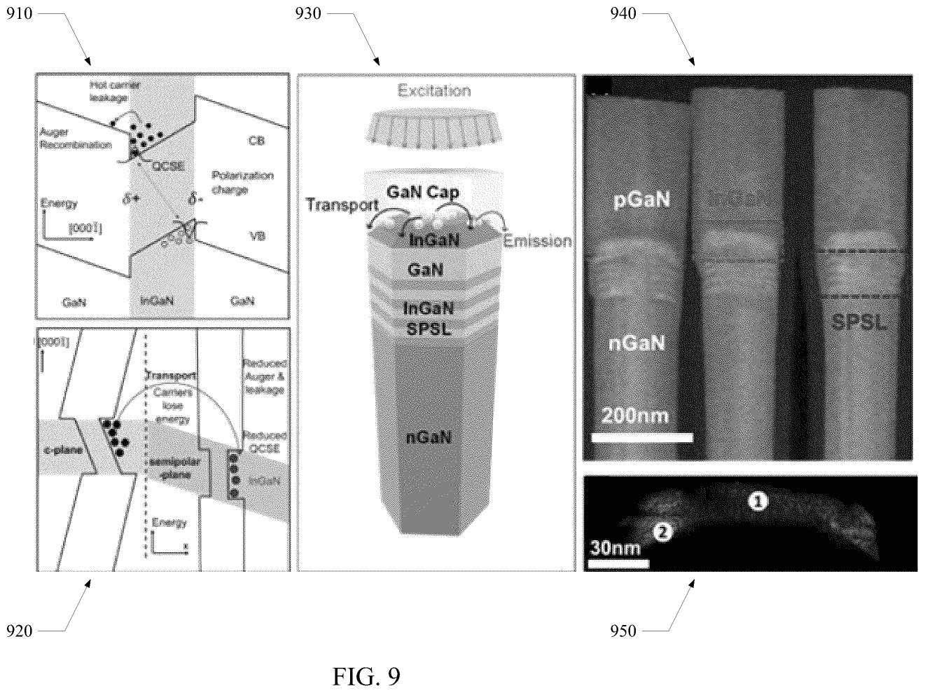

In accordance with aspects of the present technology, a charge carrier transfer process is achieved in InGaN/GaN nanowire heterostructures, wherein InGaN with different Indium (In) compositions are spontaneously formed on a c-plane and semipolar-plane, respectively. Referring now to FIG. 9, aspects of a μLED device including an N-polar quantum-confined active region having both c-plane and semipolar plane lattice, along with comparison to other conventional μLEDs, is shown. As schematically shown 920 photoinduced charge carriers in c-plane InGaN re-localize to the semipolar-plane InGaN through a nonradiative transfer process and then radiatively recombine, which leads to efficient emissions over a wide excitation power range. Additionally, in a strain relaxed InGaN/GaN heterostructure, the piezoelectric field can cancel the spontaneous polarization and can reduce the quantum confined stark effect (QCSE) as depicted 920. In comparison, the incorporation of high indium composition causes alloy substitution disorder in the active region and reduces the excitation binding energy, which enhances the Auger recombination. Polar nitrides also suffer from quantum confined stark effect (QCSE) due to spontaneous and piezoelectric polarization, which reduces the overlap of electron-hole wavefunctions and causes color instability, as depicted 910.

In one embodiment, a group micrometer or sub-micrometer nanowire light emitting device can be grown utilizing a selective area epitaxy fabrication process. In one implementation, a InGaN/GaN nanowire heterostructure can be grown using selective area epitaxy (SAE) in a Veeco Gen 930 plasma-assisted molecular beam epitaxy (PA-MBE) system. A prepatterned N-polar GaN on sapphire substrate can be used as a template for the growth. The epitaxy can begin with growing a 500 nm long Si-doped GaN nanowire segment, followed by growing a short period superlattice (SPSL) consisting of 4 pairs of InGaN/GaN (thicknesses ˜8 nm/8 nm) for the purpose of reducing dislocations and effective strain relaxation in the subsequent high indium composition InGaN active region epitaxy. An active region consists of a 25 nm thick InGaN segment, which is enclosed by GaN barriers, can be grown on the short period superlattice (SPSL) segment of the nanowire by the epitaxy process.

The structural properties of the as-grown InGaN/GaN nanostructure were characterized using scanning transmission electron microscopy (STEM). A representative low magnification high angle annular dark-field (HAADF) image of the nanowire array, wherein each layer is indicated by the atomic number-sensitive image contrast, is shown 940. It was observed that, for nanowires incorporating the SPSL and the active region, the center region of the InGaN is incorporated on the polar c-plane while the edge is on the semipolar-plane, which can be attributed to the unique partial faceting toward the nanowire sidewalls during the initial GaN elongation. The indium map of the InGaN active region, shown in 940 was collected by the electron dispersive spectroscopy (EDS). The estimated indium compositions from c-plane and semipolar-plane are around 33% and 40% respectively. The enhanced indium composition on the semipolar plane can be attributed to a combined effect of effective radial strain relaxation process and adatom diffusion mechanism during the nanostructure epitaxy.

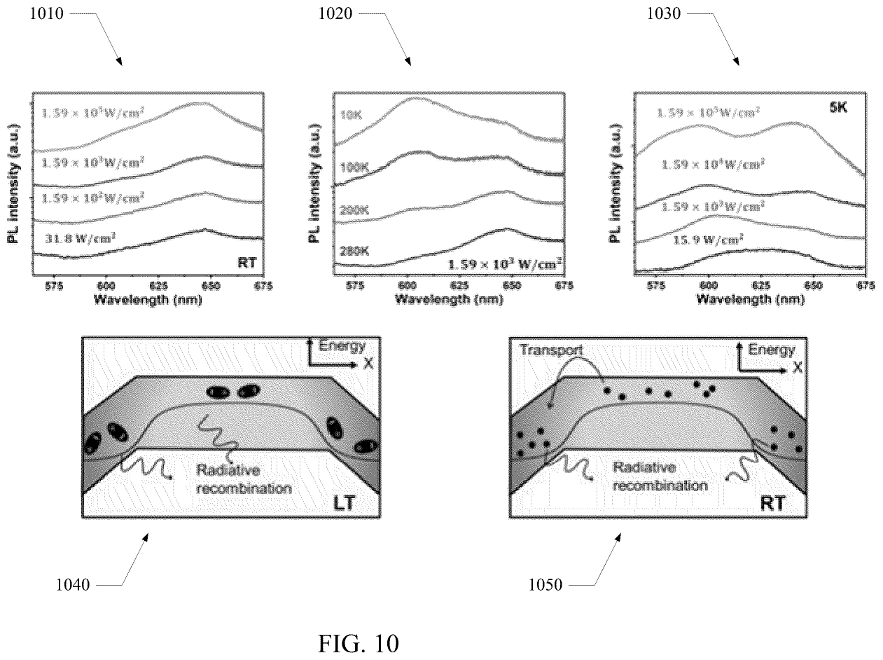

Referring to FIG. 10, photoluminescence spectra and energy transfer mechanisms, in accordance with aspects of the present technology, are shown. The luminescence properties of the as-grown InGaN/GaN heterostructure were investigated by photoluminescence spectroscopy. Temperature and power dependent photoluminescence measurements were performed using an open loop liquid helium cooled cryostat and a continuous wave (CW) 405 nm diode laser as excitation. The laser beam is focused by a 100× objective and the estimated excitation spot size is 4 μm. The measurement results are plotted with respect to excitation power density, however, the absorption efficiency for this structure is estimated to be ≈6.3%. The typical emission spectra in the red wavelength regime of the as-grown sample under various excitation powers at room temperature is shown 1010. Strong photoluminescence signals were observed in the InGaN segment on semipolar-plane with a dominant peak around 648 nm, but the photoluminescence is significantly quenched in c-plane InGaN region over a wide excitation power range. Typical photoluminescence spectra measured at various temperatures is shown 1020. It is apparent that the photoluminescence intensity in the c-plane InGaN increases with decreasing temperature and the 600 nm peak dominates at 10 K. Generally, the quenching of photoluminescence from a higher energy transition (600 nm resonance in c-plane InGaN) along with the enhancement of luminescence from the lower energy transition (648 nm resonance in semipolar-plane InGaN) indicates an energy transfer mechanism. Indeed, the charge carrier transfer depends on the degree of carrier localization. As schematically shown in 1040, at cryogenic temperatures, the photoinduced carriers stay in the form of bounded excitons, and it has been reported that strongly localized states hinder the energy transfer. When the temperature increases, the thermal energy reduces the degree of localization and free carriers predominantly contribute to the transfer process, as shown in 1050, as evidenced by the stronger emission in semipolar-plane InGaN.

Unlike the conventional InGaN quantum wells wherein strong radiative emissions are based on the presence of large number of photo-induced/electrically injected charge carriers, the charge carrier transfer mechanism does not require high charge density instantaneously but can provide efficient and strong luminescence through nonradiative transfer process from the excited c-plane InGaN to semipolar-plane InGaN over an extended temporal domain. Furthermore, excitons disassociate when the screening length is exceeded by the Bohr radius, which is ˜3×10−9 m for InGaN. This happens when the charge density exceeds the critical charge density ≈1.2×10¹⁸ cm⁻³. FIG. 10C shows the photoluminescence under various excitation powers at 10 K. An initial fast increase of the emissions in c-plane InGaN along with a blue shift in peak energy is observed, indicating the screening of quantum confined stark effect (QCSE). Further increasing the excitation power leads to strong emissions in semipolar-plane InGaN, as expected for free carrier dominated charge carrier transfer.

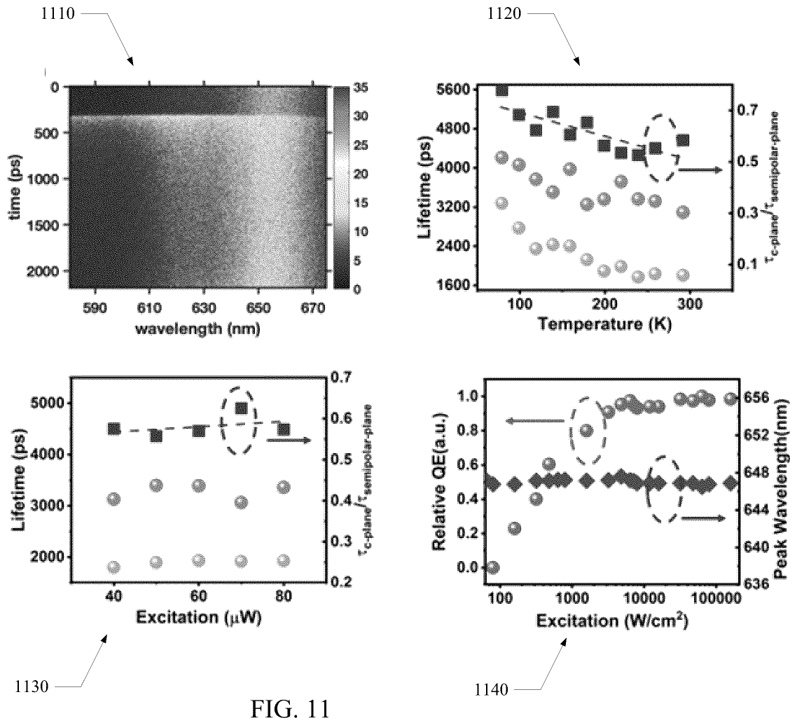

The charge carrier dynamics were further investigated by time-resolved photoluminescence. A 90 femtoseconds (fs) ultra-fast pulse with a central wavelength of 400 nm and a bandwidth of 12.5 nm is used to pump the sample at a repetition rate of 76 MHz. The sample was housed in an open-loop liquid nitrogen cooled cryostat and the temperature was controlled between 77 K and 290 K. The spot diameter of pump beam was estimated to be around 30 μm. The power of the pump light ranged from 40 μW to 80 μW, and the photoluminescence signal was recorded using a streak camera (Hamamatsu C10910). Referring now to FIG. 11, photoluminescence, radiative lifetime emission, relative quantum efficiency and peak wavelength, in accordance with aspects of the present technology, is shown. A typical streak camera image of the InGaN emission at room temperature is shown 1110. Photoluminescence signals of comparable intensities were observed initially from the c-plane and semipolar-plane InGaN, followed by a rapid decay of the emissions in c-plane InGaN, while emissions in the semipolar-plane InGaN decay over an extended time of 3.2 ns, which agrees with the proposed charge carrier transfer mechanism. The PL signal before excitation measured around 650 nm comes from the residue of PL from last pulse excitement, indicating a very long lifetime component, which is determined by the repetition rate of the pump laser. This shows that some parts of the carrier stay in the local state or surface state in the semipolar-plane region after the excitation and transportation. The transient photoluminescence was then measured at cryogenic temperatures and the average data was analyzed using a biexponential function, I(t)∝A·e^{-(t/τ}^{₁}⁾+B·e^{-(t/τ}^{₂}⁾, where τ₁ is the long lifetime representing the radiative decay process. The radiative recombination lifetimes in both c-plane and semipolar-plane InGaN increase with decreasing temperature, which can be attributed to the deactivation of defects and trap states at low temperatures, as shown in 1120. Meanwhile, the ratio of charge carrier lifetime of c-plane InGaN to semipolar-plane InGaN increases as the temperature decreases, as expected due to the formation of bounded excitons and suppressed energy transfer.

The effect of varying the excitation power of the pulse on the carrier lifetime ratio was studied at room temperature. As shown in 1130, a nearly invariant lifetime ratio with excitation power is observed at room temperature as the energy transfer varies insignificantly in thermalized free-carrier regime, which is consistent with the dominant semipolar-plane emissions as shown in 1010. The red circles in 1140 are the relative QE measured under varying excitation power at room temperature. The QE was calculated by choosing a wavelength range of 20 nm centered around 648 nm, the wavelength of interest. The emission from the superlattice has not been considered in our calculations here. The calculated value of the internal quantum efficiency (IQE) for this sample is ˜17%. A slow rise of the relative external quantum efficiency (EQE) was observed, after which it remains nearly constant over an excitation power range of 2 orders of magnitude. Here the initial rising trend can be attributed to the increasing energy transfer rate with excitation power. The lack of efficiency droop under high excitation power indicates low instantaneous charge density in the semipolar-plane InGaN, which would not cause significant non-radiative recombination process such as Auger recombination.

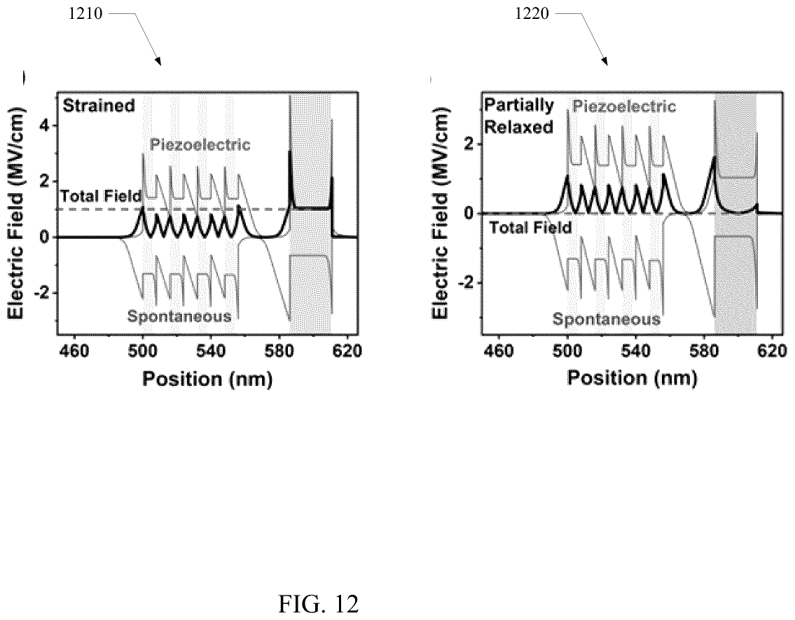

Among the studied samples, we consistently observed an invariance in the emission peak energies in semipolar-plane InGaN over a wide excitation power range, as represented by the blue diamonds in 1140, which indicates a suppressed quantum confined stark effect (QCSE) and is desirable for color stability in display applications. The built-in electric field in the InGaN/GaN heterostructure with similar structural properties as the as-grown sample was numerically calculated using Silvaco ATLAS. The simulated structure had 500 nm of nGaN, a 4×In_{0.19}Ga_{0.81}N/GaN short period superlattice (SPSL) (8 nm/8 nm) and a 25 nm In_{0.33}Ga_{0.67}N segment separated from the SPSL by a 30 nm GaN spacer. The InGaN compositions were chosen based on the measured photoluminescence (PL) spectra. To study the effect of strain relaxation on built-in field, we consider two cases. The first case is a fully strained InGaN/GaN heterostructure where we assume 100% contribution of the lattice mismatch to strain. To account for the effect of surface relaxation in nanostructures and the utilization of short period superlattice (SPSL) preceding the InGaN active region, we simulate the second case assuming that only 50% of the strain without surface relaxation presents itself in the active region. The parameters for spontaneous and piezoelectric polarization, elastic constants, and lattice constants were based on previous reports. The net-induced fields due to spontaneous polarization and piezoelectric polarization are calculated as shown in FIG. 12. In compressively strained InGaN active region, the opposite directions between spontaneous and piezoelectric fields can be employed to reduce the total built-in electric field. However, as the absolute magnitude of the piezoelectric field well exceeds that of spontaneous polarization field in fully strained InGaN/GaN heterostructure, the estimated total built-in field is about 1 MV/cm as shown in 1210, which induces significant quantum confined stark effect (QCSE) especially in high indium composition InGaN active region. In contrast, the partially strain relaxed InGaN features reduced piezoelectric field, which is effectively balanced by the spontaneous polarization and results in a significantly reduced total built-in field of ≈6 kV/cm in the active region as shown in 1220. Built-in electric field of several kV/cm results in a negligible quantum confined stark effect (QCSE) as evidenced by the nearly invariant peak energies shown in 11D.

In summary, the charge carrier transfer between c-plane and semipolar-plane InGaN provides for efficient radiative recombination over a wide excitation power range. The transfer process alleviates the nonradiative Auger recombination and ensures strong red emission from the InGaN active region. Through detailed numerical calculation and analysis of the photoluminescence spectra, the piezoelectric polarization and spontaneous polarization nearly cancels each other in strain-relaxed high indium composition InGaN. Consequently, the built-in electric field is reduced by nearly 3 orders of magnitude and negligible quantum confined stark effect (QCSE) is achieved. This study is critical in understanding the carrier dynamics in nanowire heterostructures. The devices, processes and mechanisms in accordance with aspects of the present technology are advantageous for the design of a wide range devices that emit photons in the ultraviolet, visible and infrared regimes.

The following examples pertain to specific technology embodiments and point out specific features, elements, or steps that may be used or otherwise combined in achieving such embodiments.

Example 1 includes a light emitting device comprising: a photonic crystal component; and a N-polar nanowire component.

Example 2 includes the light emitting device of Example 1, wherein the N-polar nanowire component includes an indium gallium nitride and gallium nitride (InGaN/GaN) multiple quantum-dot (MQC) active region.

Example 3 includes the light emitting device of Example 1, wherein the N-polar nanowire component includes a core-shell nano structure and polarization doping.

Example 4 includes the light emitting device of Example 1, wherein wavelengths of light are controlled by varying the N-polar nanowire component configuration.

Example 5 includes a light emitting device comprising N-polar nanowire structures, wherein a wavelength of light is tunable.

Example 6 includes the light emitting device of Example 5, wherein the wavelength is controlled by configuration of the N-polar nanowire structures, including varying a diameter of the N-polar nanowire structure.

Example 7 includes the light emitting device of Example 5, wherein the wavelength is controlled by configuration of the N-polar nanowire structures, including varying the spacing between the N-polar nanowire structures.

Example 8 includes a light emitting device comprising a c-plane to semipolar-plane transition in a nanowire heterostructure.

Example 9 includes the light emitting device of Example 1, wherein the c-plane to semipolar-plane transition comprises a spontaneously formed c-plane to semipolar-plane transition in a multi-quantum well active region.

Example 10 includes the light emitting device of Example 1, wherein the c-plane to semipolar-plane transition in the nanowire heterostructure reduces a charge carrier density in an active region.

Example 11 includes the light emitting device of Example 1, wherein the c-plane to semipolar-plane transition in the nanowire heterostructure enhances emission efficiency in a red wavelength.

Example 12 includes the light emitting device of Example 1, wherein the nanowire heterostructure is strain-relaxed.

Example 13 includes the light emitting device of Example 12, wherein a piezoelectric polarization is reduced with spontaneous polarization in the strain-relaxed nanowire heterostructure.

Example 14 includes the light emitting device of Example 1, wherein a red emission color is stable over for orders of magnitude of an excitation power range.

Example 15 includes the light emitting device of Example 1, wherein the nanowire heterostructure comprises a multiple quantum well active region disposed on a strain relaxed superlattice structure.

Example 16 includes the light emitting device of Example 1, wherein the nanowire heterostructure comprises a micrometer or sub-micrometer nanowire heterostructure.

Example 17 includes an optoelectronic device comprising a c-plane to semipolar-plane transition in a quantum w-ell active region.

Example 18 includes the optoelectronic device of Example 17, wherein the quantum well active region comprises a group III-nitride quantum well active region.

Example 19 includes the optoelectronic device of Example 17, wherein the quantum well active region comprises an indium gallium nitride quantum well active region.

Example 20 includes the optoelectronic device of Example 19, wherein the indium gallium nitride quantum well active region comprises:
one or more indium gallium nitride quantum well layers disposed between gallium nitride barrier layers.

Example 21 includes the optoelectronic device of Example 17, further comprising a strain relaxed superlattice structure upon which the quantum well active region is disposed.

Example 22 includes the optoelectronic device of Example 21, wherein the strain relaxed superlattice structure comprises a strain relaxed short period superlattice (SPSL) region.

Example 23 includes the optoelectronic device of Example 22, wherein the strain relaxed superlattice structure comprises a plurality of pairs of indium gallium nitride and gallium nitride layers.

Example 24 includes the optoelectronic device of Example 17, wherein the c-plane is disposed in a center region of the quantum well active region and the semipolar-plane is disposed on an edge of the quantum well active region.

Example 25 includes the optoelectronic device of Example 17, wherein a concentration of indium in the c-plane is approximately 33% and the concentration of indium in the semipolar-plane is approximately 40%.

Example 26 includes the optoelectronic device of Example, wherein the quantum well active region has a micrometer or sub-micrometer width.

Example 27 includes a method of fabricating a light emitting device comprising: forming a superlattice structure; and forming a quantum well active region including a c-plane to semipolar-plane transition on the superlattice structure.

Example 29 includes the method according to Example 27, wherein forming the quantum well active region comprises: epitaxially depositing a plurality of gallium nitride barrier layers; and epitaxially depositing one or more indium gallium nitride quantum well layers, wherein the indium gallium nitride quantum layers are disposed between the gallium nitride barrier layers.

Example 30 includes the method according to Example 28, wherein the c-plane is disposed in a center region of the indium gallium nitride quantum well layers and the semipolar-plane is disposed on an edge of the gallium nitride quantum well layers.

Example 31 includes the method according to Example 28, wherein a concentration of indium in the center regions of the indium gallium nitride quantum well layers is approximately 33% and the concentration of indium in the edges of the gallium nitride quantum well layers is approximately 40%.

Example 32 includes the method according to Example 27, wherein forming the superlattice structure comprises: epitaxially depositing a plurality of pairs of indium gallium nitride and gallium nitride layers.

Example 33 includes the method according to Example 32, wherein forming the superlattice structure further comprises: relaxing strain in the to plurality of pairs of indium gallium nitride and gallium nitride layers form a short period superlattice (SPSL) structure.

Example 34 includes the method according to Example 27, wherein the quantum well active region and the superlattice structure are formed by plasma-assisted molecular beam epitaxy (PA-MBE).

Example 35 includes the method according to Example 27, wherein the quantum well active region and the superlattice structure have a micrometer or sub-micrometer width.

The foregoing descriptions of specific embodiments of the present technology have been presented for purposes of illustration and description. They are not intended to be exhaustive or to limit the invention to the precise forms disclosed, and obviously many modifications and variations are possible in light of the above teaching. The embodiments were chosen and described in order to best explain the principles of the present technology and its practical application, to thereby enable others skilled in the art to best utilize the present technology and various embodiments with various modifications as are suited to the particular use contemplated.

1. A light emitting device comprising:
a photonic crystal component; and
a N-polar nanowire component.

2. The light emitting device of claim 1, wherein the N-polar nanowire component comprises a plurality of c-plane N-polar quantum-confined indium gallium nitride (InGaN) nanostructures.

3. The light emitting device of claim 2, wherein the photonic crystal component comprises the plurality of N-polar quantum-confined indium gallium nitride (InGaN) nanostructures having sub-micrometer cross-sectional nanostructure width and sub-micrometer nanostructure lattice constant length.

4. The light emitting device of claim 3, wherein the cross-sectional nanostructure width and sub-micrometer nanostructure lattice constant length is selected for green light emission by the light emitting device.

5. The light emitting device of claim 4, wherein the N-polar nanowire component comprises a plurality of c-plane N-polar indium gallium nitride (InGaN) and gallium nitride (GaN) multiple quantum dot (MQD) nanostructures.

6. The light emitting device of claim 3, wherein the cross-sectional nanostructure width and sub-micrometer nanostructure lattice constant length is selected for red light emission by the light emitting device.

7. The light emitting device of claim 6, wherein the N-polar nanowire component comprises a plurality of c-plane N-polar nanostructures including an indium gallium nitride (GaN) single segment (SS) active region disposed on a indium gallium nitride (InGaN) and gallium nitride (GaN) short-period superlattice (SPS).

8. The light emitting device of claim 2, wherein the plurality of c-plane N-polar quantum confined indium gallium nitride (InGaN) nanostructures include a semipolar transition between the c-plane nanostructure face and nanostructure walls.

9. The light emitting device of claim 2, wherein the plurality of c-plane N-polar quantum confined indium gallium nitride (InGaN) nanostructures includes both a c-plane and semi-polar plane lattice in a faceted active region.

10. A method of manufacturing a light emitting device comprising:
bottom-up fabricating a plurality of type III-V semiconductor nanostructures in a photonic crystal on an N-polar template.

11. The method according to claim 10, wherein bottom-up fabricating a plurality of type III-V semiconductor nanostructures in a photonic crystal comprises:
selective area epitaxy depositing N-polar quantum-confined indium gallium nitride (InGaN) nanostructures having sub-micrometer cross-sectional nanostructure width and sub-micrometer nanostructure lattice constant length.

12. The method according to claim 11, wherein selective area epitaxy depositing N-polar quantum-confined indium gallium nitride (InGaN) nanostructures comprise selective area plasma-assisted molecular beam epitaxy (PA-MBE) depositing a plurality of c-plane N-polar indium gallium nitride (InGaN) and gallium nitride (GaN) multiple quantum dot (MQD) nanostructures.

13. The method according to claim 12, wherein the nanostructures including the quantum dot (MQD) nanostructures have a sub-micrometer cross-sectional nanostructure width and sub-micrometer nanostructure lattice constant length configured for green light emission by the light emitting device.

14. The method according to claim 11, wherein selective area epitaxy depositing N-polar quantum-confined indium gallium nitride (InGaN) nanostructures comprises:
selective area plasma-assisted molecular beam epitaxy (PA-MBE) depositing gallium nitride (GaN) short-period superlattice (SPS) regions; and
selective area plasma-assisted molecular beam epitaxy (PA-MBE) depositing a c-plane N-polar indium gallium nitride (InGaN) and gallium nitride (GaN) single segment (SS) active region on the gallium nitride (GaN) short-period superlattice (SPS) regions.

15. The method according to claim 14, wherein the nanostructures including the single segment (SS) active region and short-period superlattice (SPS) regions have a sub-micrometer cross-sectional nanostructure width and sub-micrometer nanostructure lattice constant length configured for red light emission by the light emitting device.

16. The method according to claim 11, wherein the selective area epitaxy depositing N-polar quantum-confined indium gallium nitride (InGaN) nanostructures include a semipolar transition between a c-plane face and sidewalls of the N-polar quantum-confined indium gallium nitride (InGaN) nanostructures.

17. A light emitting device comprising: a plurality of nanostructures including N-polar quantum-confined active regions have both c-plane and semipolar plane lattice, wherein the plurality of nanostructures have a sub-micrometer cross-sectional width and sub-micrometer separation between the plurality of nanostructures.

18. The light emitting device of claim 17, wherein the N-polar quantum-confined active regions comprise N-polar indium gallium nitride (InGaN) and gallium nitride (GaN) multiple quantum dot (MQD) nanostructures having a semipolar transition between a c-plane face and walls of the plurality of nanostructures.

19. The light emitting device of claim 17, wherein the N-polar quantum-confined active regions comprise N-polar nanostructures including an indium gallium nitride (GaN) single segment (SS) active region disposed on indium gallium nitride (InGaN) and gallium nitride (GaN) short-period superlattice (SPS) having a semipolar transition between a c-plane face and walls of the plurality of nanostructures.

20. A method of manufacturing a light emitting device comprising bottom-up fabricating a plurality of nanostructures including N-polar quantum-confined active regions having a semipolar plane lattice transition between a c-plane lattice face and sidewalls of the quantum-confined active regions.

21. The method according to claim 20, wherein bottom-up fabricating the plurality of nano-structures comprises:
selective area epitaxy depositing gallium nitride (GaN) short-period superlattice (SPS) regions, wherein epitaxy deposition parameters are configured to deposit the gallium nitride (GaN) with a nitride termination; and
selective area epitaxy depositing indium gallium nitride (InGaN) and gallium nitride (GaN) single segment (SS) active regions on the gallium nitride (GaN) short-period superlattice (SPS) regions, wherein the epitaxy deposition parameters are configured to deposit the indium gallium nitride (InGaN) and gallium nitride (GaN) single segment (SS) with the nitride-termination, a c-plane lattice on a face of the indium gallium nitride (InGaN) and gallium nitride (GaN), and a spontaneously formed semipolar transition between the c-plane lattice of the face and sidewalls of the indium gallium nitride (InGaN) and gallium nitride (GaN).

22. The method according to claim 20, wherein the plurality of nanostructures are fabricated to have a sub-micrometer cross-sectional width and a sub-micrometer separation between the plurality of nanostructures.
